(19) United States
(12) Patent Application Publication
(10) Pub. No.: US 2023/0361215 A1
(43) Pub. Date: Nov. 9, 2023

(54) SEMICONDUCTOR DEVICE

(71) Applicant: Samsung Electronics Co., Ltd., Suwon-si (KR)

(72) Inventors: Gyeom Kim, Suwon-si (KR); Daehong Ko, Goyang-si (KR); Jinbum Kim, Suwon-si (KR); Sangmoon Lee, Suwon-si (KR); Daeseop Byeon, Seoul (KR); Seran Park, Pyeongtaek-si (KR); Hyunsu Shin, Pyeongtaek-si (KR); Kiseok Lee, Seoul (KR); Chunghee Jo, Seoul (KR)

(73) Assignees: Samsung Electronics Co., Ltd., Suwon-si (KR); Industry-Academic Cooperation Foundation, Yonsei University, Seoul (KR)

(21) Appl. No.: 18/133,730

(22) Filed: Apr. 12, 2023

(30) Foreign Application Priority Data
May 9, 2022 (KR) 10-2022-0056358

(51) Int. Cl. H01L 29/66; H01L 29/78

(52) U.S. Cl. CPC H01L 29/7851; H01L 29/66545; H01L 29/6656

(57) ABSTRACT

A semiconductor device including a substrate extending in a first direction and a second direction perpendicular to the first direction, a first active pattern protruding from a top surface of the substrate and extending in the first direction, an isolation pattern covering a sidewall of the first active pattern on the substrate, first silicon patterns spaced apart from each other in a third direction on the first active pattern, the third direction perpendicular to the first direction and second direction, a first source/drain layer extending in the third direction from a top surface of the first active pattern on the first active pattern, and in contact with sidewalls of the first silicon patterns, wherein a sidewall of the first source/drain layer in the second direction has a constant inclination with respect to the top surface of the substrate, and a gate structure extending in the second direction while filling a gap between the first silicon patterns on the substrate.

### CROSS-REFERENCE TO RELATED APPLICATION

This application claims priority under 35 USC § 119 to Korean Patent Application No. 10-2022-0056358 filed on May 09, 2022 in the Korean Intellectual Property Office (KIPO), the entire disclosure of which is incorporated herein by reference.

### BACKGROUND

### 1. Field

Embodiments of the present disclosure relate to a semiconductor device and a method of manufacturing the same. More particularly, embodiments of the present disclosure relate to a semiconductor device having a multi-bridge channel transistor (MBC FET) and a method of manufacturing the same.

### 2. Description of the Related Art

A multi-bridge channel transistor including a plurality of channels that are vertically stacked may be configured such that a source/drain layer commonly making contact with the channels may be formed. The source/drain layer may be required to be formed through a simple process.

### SUMMARY

Example embodiments provide a semiconductor device having excellent characteristics.

Example embodiments provide a method of manufacturing a semiconductor device having excellent characteristics and formed through a simple process.

According to embodiments of the present disclosure, a semiconductor device includes: a substrate extending in a first direction and a second direction perpendicular to the first direction; a first active pattern protruding from a top surface of the substrate and extending in the first direction; an isolation pattern covering a sidewall of the first active pattern on the substrate; first silicon patterns spaced apart from each other in a third direction on the first active pattern, the third direction perpendicular to the first direction and the second direction; a first source/drain layer extending in the vertical direction from a top surface of the first active pattern on the first active pattern, and in contact with sidewalls of the first silicon patterns, wherein a sidewall of the first source/drain layer in the second direction has a constant inclination with respect to the top surface of the substrate; and a gate structure extending in the second direction while filling a gap between the first silicon patterns on the substrate.

According to embodiments of the present disclosure, a semiconductor device includes: a substrate extending in a first direction and a second direction perpendicular to the first direction; a first active pattern protruding from a top surface of the substrate in a first region and extending in the first direction; first silicon patterns spaced apart from each other in a third direction on the first active pattern, the third direction perpendicular to the first direction and the second direction; a first source/drain layer extending in the third direction from a top surface of the first active pattern on the first active pattern, and in contact with sidewalls of the first silicon patterns, wherein a sidewall of the first source/drain layer the a second has a constant inclination with respect to the top surface of the substrate; a second active pattern protruding from the top surface of the substrate in a second region and extending in the first direction; second silicon patterns spaced apart from each other in the third direction on the second active pattern; a second source/drain layer extending in the third direction from a top surface of the second active pattern on the second active pattern, and in contact with sidewalls of the second silicon patterns, in which a sidewall of the second source/drain layer in the second direction has a profile in which a portion protrudes; a first gate structure extending in the second direction while filling a gap between the first silicon patterns on the substrate; and a second gate structure extending in the second direction while filling a gap between the second silicon patterns on the substrate.

According to embodiments of the present disclosure, a semiconductor device includes: a substrate extending in a first direction and a second direction perpendicular to the first direction; a first active pattern protruding from a top surface of the substrate in a first region and extending in the first direction; first silicon patterns spaced apart from each other in a third direction on the first active pattern, the third direction perpendicular to the first direction and the second direction; a first source/drain layer extending in the third direction from a top surface of the first active pattern on the first active pattern, in contact with sidewalls of the first silicon patterns, and including single crystal silicon germanium doped with P-type impurities; a second active pattern protruding from the top surface of the substrate in a second region and extending in the first direction; second silicon patterns spaced apart from each other in the third direction on the second active pattern; a second source/drain layer extending in the third direction from a top surface of the second active pattern on the second active pattern, in contact with sidewalls of the second silicon patterns, and including silicon including germanium doped with N-type impurities; a first gate structure extending in the second direction while filling a gap between the first silicon patterns on the substrate; and a second gate structure extending in the second direction while filling a gap between the second silicon patterns on the substrate, wherein each of sidewalls of the first and second source/drain layers in the second direction has a vertical profile or has an inclination such that a width of each of the first source/drain layer and the second source/drain layer in the second direction increases along the third direction.

According to the semiconductor device of exemplary embodiments, the first source/drain layer may not be formed through a selective epitaxial growth process, so that the sidewall of the first source/drain layer can be prevented from having a profile in which a portion protrudes. The first source/drain layer may be formed through an ion implantation process and an annealing process, so that the first source/drain layer can be easily formed.

### BRIEF DESCRIPTION OF THE DRAWINGS

FIGS. 1 to 3 are perspective and sectional views for describing a semiconductor device according to exemplary embodiments.

FIG. 4 is a sectional view showing a semiconductor device according to some exemplary embodiments.

FIGS. 5 to 13 are sectional views for describing a method of manufacturing a semiconductor device according to exemplary embodiments.

FIGS. 14 to 18 are perspective and sectional views for describing a semiconductor device according to exemplary embodiments.

FIG. 19 is a sectional view showing a semiconductor device according to some exemplary embodiments.

FIGS. 20 to 28 are sectional views for describing a method of manufacturing a semiconductor device according to exemplary embodiments.

FIGS. 29 to 33 are perspective and sectional views for describing a semiconductor device according to exemplary embodiments.

FIGS. 34 to 37 are perspective and sectional views for describing a semiconductor device according to exemplary embodiments.

### DETAILED DESCRIPTION OF THE EMBODIMENTS

Hereinafter, exemplary embodiments of the present disclosure will be described in detail with reference to the accompanying drawings.

Hereinafter, one direction that is parallel to a surface of a substrate will be referred to as a first direction (e.g., X direction), and a direction that is parallel to the surface of the substrate and perpendicular to the first direction will be referred to as a second direction (e.g., Y direction). In addition, a direction that is perpendicular to the surface of the substrate will be referred to as a vertical or third direction (e.g., Z direction).

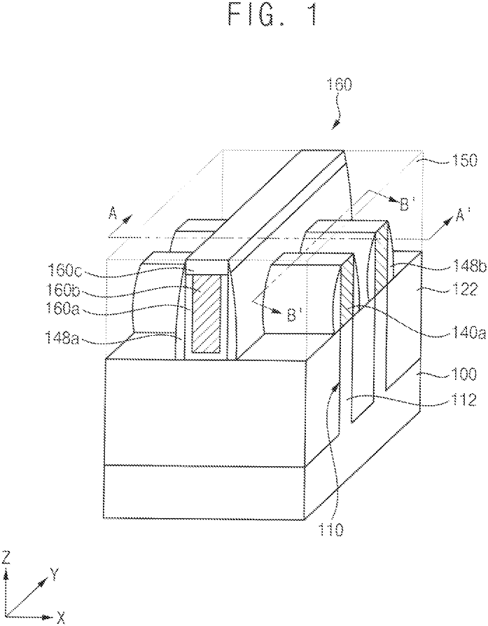

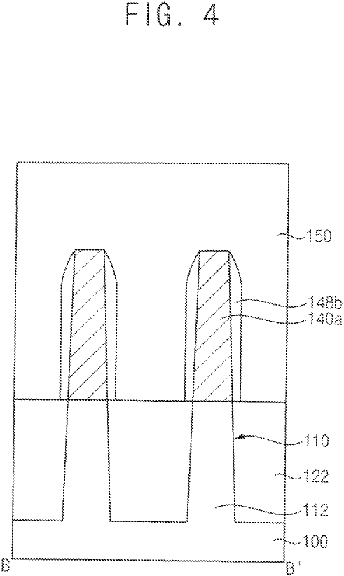

FIGS. 1 to 3 are perspective and sectional views for describing a semiconductor device according to exemplary embodiments. FIG. 4 is a sectional view showing a semiconductor device according to some exemplary embodiments.

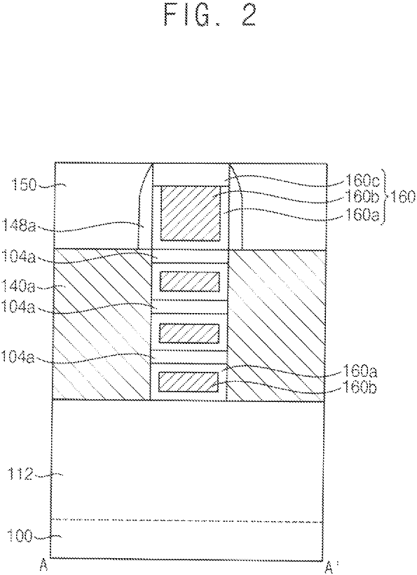

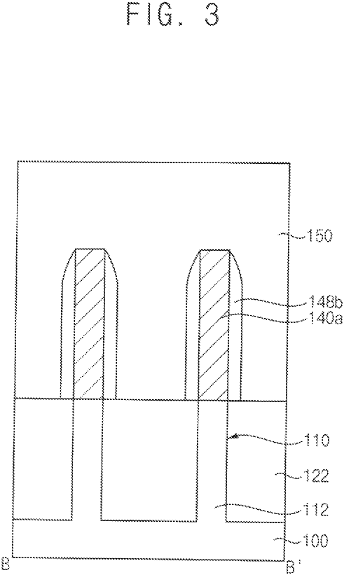

In detail, FIG. 1 is a perspective view, FIG. 2 is a sectional view taken along a line A-A′ of FIG. 1, and FIG. 3 is a sectional view taken along a line B-B′ of FIG. 1. FIG. 4 is a sectional view taken along the line B-B′ of FIG. 1.

Referring to FIGS. 1 to 3, the semiconductor device may include a P-type MBC FET formed on a substrate 100.

The semiconductor device may include a first active pattern 112, a gate structure 160, first silicon patterns 104a, a first source/drain layer 140a, and first and second spacers 148a and 148b. In addition, the semiconductor device may further include an isolation pattern 122 and an interlayer insulating layer 150.

The first active pattern 112 may be formed by etching a portion of the substrate 100. Therefore, the first active pattern 112 may have a shape protruding from a top surface of the substrate 100. A first trench 110 may be provided on both sides of the first active pattern 112. According to exemplary embodiments, the first active pattern 112 may extend in the first direction X. A plurality of first active patterns 112 may be arranged in parallel to each other while being spaced apart from each other in the second direction Y.

Although two first active patterns 112 have been shown in the drawings, the concept of the present disclosure is not limited thereto, and one first active pattern 112 or at least three first active patterns 112 may be provided while being spaced apart from each other in the second direction Y.

The substrate 100 may include single crystal silicon. Since the first active pattern 112 is formed by partially etching an upper portion of the substrate 100, the first active pattern 112 may include the same material as the substrate, for example, single crystal silicon.

The isolation pattern 122 may be provided within the first trench 110 provided on the both sides of the first active pattern 112. The isolation pattern 122 may cover a sidewall of the first active pattern 112. The isolation pattern 122 may be provided between the first active patterns 112 so that adjacent first active patterns 112 may be electrically insulated from each other by the isolation pattern 122.

A plurality of first silicon patterns 104a spaced apart from each other in the vertical direction from a top surface of the first active pattern 112 may be provided. The first silicon patterns 104a may be provided as channels of the P-type MBC FET.

The first silicon patterns 104a may include single crystal silicon. Although the first silicon patterns 104a have been shown in the drawings as being formed as three layers, the concept of the present disclosure is not limited thereto.

The first source/drain layer 140a may extend in the vertical direction from the top surface of the first active pattern 112, and may be in contact with sidewalls of the first silicon patterns 104a in the first direction, in which the first silicon patterns 104a are spaced apart from each other in the vertical direction. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

A space defined by the first source/drain layer 140a and a region in which the first silicon patterns 104a are spaced apart from each other in the vertical direction will be referred to as a first gap.

The gate structure 160 may be formed on the isolation pattern 122 and the first active pattern 112, and may extend in the second direction while filling the first gap. The gate structure 160 may cover the first silicon patterns 104a. A top surface of the gate structure 160 may be located higher (e.g., in the vertical (Z) direction) than a top surface of an uppermost first silicon pattern 104a. The top surface of the gate structure 160 may be flat (e.g., substantially planar). Terms such as “same,” “equal,” “planar,” or “coplanar,” as used herein encompass identicality or near identicality including variations that may occur, for example, due to manufacturing processes. The term “substantially” may be used herein to emphasize this meaning, unless the context or other statements indicate otherwise.

Meanwhile, although one gate structure 160 has been shown in the drawings as being formed on the substrate 100, the concept of the present disclosure is not limited thereto, and a plurality of gate structures 160 spaced apart from each other in the first direction may be formed.

The first source/drain layer 140a may be disposed on both sides of the gate structure 160 formed within the first gap. The both sides of the gate structure 160 may be in contact with the first source/drain layer 140a.

The first source/drain layer 140a may include single crystal silicon germanium. The first source/drain layer 140a may be doped with P-type impurities. The P-type impurities may include, for example, boron, gallium, or carbon. These may be used alone, or two or more of these may be used. Alternatively, the P-type impurities may include an element other than the above elements. According to an exemplary embodiment, the P-type impurities may have a concentration of 1E19 /cm³ to 1E22 /cm³. For example, the P-type impurities may have a high concentration of 1E20 /cm³ to 1.5E21 /cm³.

Accordingly, the first source/drain layer 140a may serve as a source/drain layer of a PMOS transistor.

The first source/drain layer 140a may have a sidewall profile formed through an anisotropic etching process. For example, the sidewall of the first source/drain layer 140a in the second direction may have a constant inclination with respect to the top surface of the substrate. A variation rate of a thickness of the first source/drain layer 140a in the second direction may be constant from a top to a bottom of the first source/drain layer 140a. Since the first source/drain layer 140a is not formed through a selective epitaxial growth (SEG) process, the first source/drain layer 140a may have a sidewall profile that is different from a sidewall profile of a layer formed through the selective epitaxial growth process. For example, the sidewall of the first source/drain layer 140a in the second direction may not have a profile in which a portion protrudes. The sidewall of the first source/drain layer 140a in the second direction may be flat (e.g., substantially planar). For example, the thickness of the first source/drain layer 140a in the second direction may be equal to a thickness of each of the first silicon patterns 104a in the second direction. In this case, a case in which the thicknesses are equal to each other may include a case in which one of the thicknesses is slightly greater or less than the remaining thickness. As another example, the thickness of the first source/drain layer 140a in the second direction may be less than the thickness of each of the first silicon patterns 104a in the second direction.

According to the exemplary embodiment, as shown in FIG. 3, the first source/drain layer 140a may have a vertical sidewall profile when viewed in a sectional view in the second direction.

In some exemplary embodiments, as shown in FIG. 4, the first source/drain layer 140a may have a sidewall profile having an inclination that allows a width to be gradually increased downward when viewed in a sectional view in the second direction.

The first source/drain layer 140a may not have a polygonal shape in which a center portion protrudes (e.g., a partial shape of a pentagon, a hexagon, or a tetragon) when viewed in a sectional view in the second direction. For example, the width of the first source/drain layer 140a in the second direction is not greatest at the center portion of the first source/drain layer 140a. The width of the first source/drain layer 140a in the second direction may remain substantially the same along the third (Z) direction. In an alternative, the width of the first source/drain layer 140a in the second direction may taper from one end of the first source/drain layer 140a to another end of the first source/drain layer 140a along the third (Z) direction.

According to the exemplary embodiments, the top surface of the first source/drain layer 140a and a top surface of the first silicon pattern 104a located at an uppermost portion may be located on the same plane. The top surface of the first source/drain layer 140a and the top surface of the first silicon pattern 104a located at the uppermost portion may not have a separate boundary or step with respect to each other.

According to the exemplary embodiment, a bottom surface of the first source/drain layer 140a may be located on the same plane as a lowermost surface of the gate structure 160 that is adjacent to the first source/drain layer 140a.

The gate structure 160 may include an interface pattern (not shown), a gate insulating pattern 160a, a gate electrode 160b, and a capping pattern 160c.

The interface pattern may include, for example, an oxide such as a silicon oxide, and the gate insulating pattern 160a may include, for example, a metal oxide having a high dielectric constant, such as a hafnium oxide, a tantalum oxide, or a zirconium oxide. The gate electrode 160b may include a metal, and may include, for example, titanium, aluminum, tungsten, or a nitride or carbide thereof. The capping pattern 160c may include a silicon nitride.

The first spacer 148a may be provided on a sidewall of the gate structure 160.

The second spacer 148b may be provided on the sidewall of the first source/drain layer 140a. The second spacer 148b may cover the sidewall of the first source/drain layer 140a in the second direction. Therefore, when viewed in a sectional view in the second direction, the second spacer 148b may completely cover the sidewall of the first source/drain layer 140a.

The first and second spacers 148a and 148b may be formed of the same material. Each of the first and second spacers 148a and 148b may include a silicon nitride, a silicon carbide, SiCN, and the like.

According to the exemplary embodiment, a bottom surface of the first spacer 148a formed on the sidewall of the gate structure 160 located on the uppermost first silicon pattern 104a may be in contact with the top surface of the first source/drain layer 140a.

The interlayer insulating layer 150 covering the isolation pattern 122, the first source/drain layer 140a, and the first and second spacers 148a and 148b may be provided. A top surface of the interlayer insulating layer 150 may be located on the same plane as the top surface of the gate structure 160. Therefore, the interlayer insulating layer 150 may cover the sidewall of the gate structure 160.

Although not shown, a contact plug passing through the interlayer insulating layer 150 to make contact with the top surface of the first source/drain layer 140a may be provided. Since the first spacer 148a is provided, a bridge defect in which the contact plug makes contact with the gate structure may be reduced.

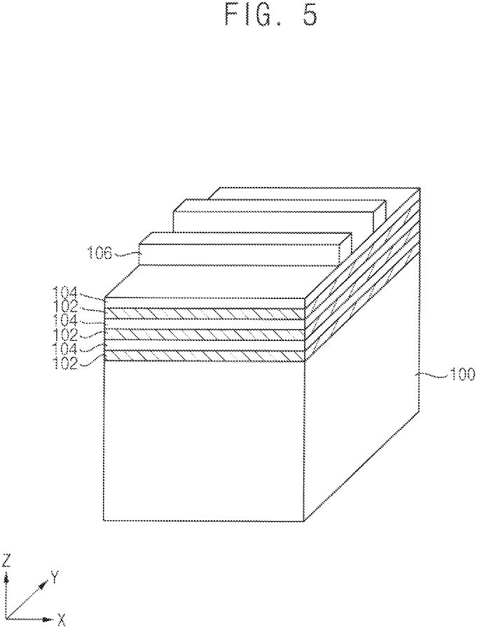

FIGS. 5 to 13 are sectional views for describing a method of manufacturing a semiconductor device according to exemplary embodiments.

Referring to FIG. 5, a silicon germanium layer 102 and a silicon layer 104 may be alternately and repeatedly stacked on a substrate 100. A mask pattern 106 may be formed on an uppermost silicon layer 104. The substrate 100 may be a single crystal silicon substrate.

The silicon germanium layer 102 and the silicon layer 104 may be formed through a selective epitaxial growth process using an upper portion of the substrate 100 as a seed.

According to one embodiment, the silicon layer 104 may be formed, for example, by performing a selective epitaxial growth process using a silicon source gas such as a disilane (Si₂H₆) gas. The silicon layer 104 may include single crystal silicon.

According to one embodiment, the silicon germanium layer 102 may be formed, for example, by performing a selective epitaxial growth process using a silicon source gas such as a dichlorosilane (SiH₂Cl₂) gas or a germanium source gas such as a germanium tetrahydride (GeH₄) gas. The silicon germanium layer 102 may include single crystal silicon germanium.

The mask pattern 106 may include, for example, a nitride such as a silicon nitride. The mask pattern 106 may have a line shape extending in the first direction X. A plurality of mask patterns 106 may be provided while being spaced apart from each other in the second direction Y.

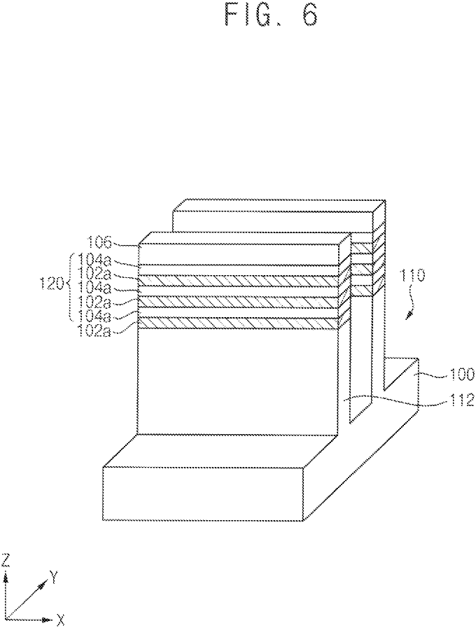

Referring to FIG. 6, first trenches 110 may be formed by etching the silicon germanium layer 102, the silicon layer 104, and an upper portion of the substrate 100 by using the mask pattern 106 as an etching mask. The etching process may include an anisotropic etching process.

Accordingly, a first active pattern 112 formed by etching the substrate 100 and extending in the first direction may be formed on the substrate 100. A first fin structure 120 including first silicon germanium patterns 102a and first silicon patterns 104a, which are alternately and repeatedly stacked, may be formed on the first active pattern 112. In other words, a structure in which the first active pattern 112, the first fin structure 120, and the mask pattern 106 are stacked may be formed between the first trenches 110.

A portion of the first fin structure may be converted into a first source/drain layer through a subsequent process. Therefore, a sidewall profile of the portion of the first fin structure in the second direction may be the same as a sidewall profile of the first source/drain layer.

The sidewall profile of the first fin structure 120 in the second direction may be a vertical profile. The sidewall profile of the first fin structure 120 in the second direction will be shown as being the vertical profile in the manufacturing process illustrated in FIGS. 6 to 13.

However, depending on characteristics of the anisotropic etching process, the sidewall profile of the first fin structure 120 in the second direction may be an inclined profile that allows a width of the first fin structure 120 to be gradually increased downward (e.g., along the third (Z) direction toward the first active pattern 112). For example, a width of the first fin structure 120 in the second direction may be greater at a first end of the first fin structure 120 in contact with the first active pattern 112 than a width of a second end of the first fin structure 120 not in contact with the first active pattern 112. In this case, a semiconductor device having a section as shown in FIG. 4 may be manufactured through a subsequent process.

Since the first fin structure 120 is patterned through the anisotropic etching process, a sidewall of the first fin structure 120 in the second direction may not have a shape protruding from a specific region. For example, the sidewall of the first fin structure 120 in the second direction may have a constant inclination with respect to a top surface of the substrate. A variation rate of a thickness of the first fin structure 120 in the second direction may be constant from a top to a bottom of the first fin structure 120.

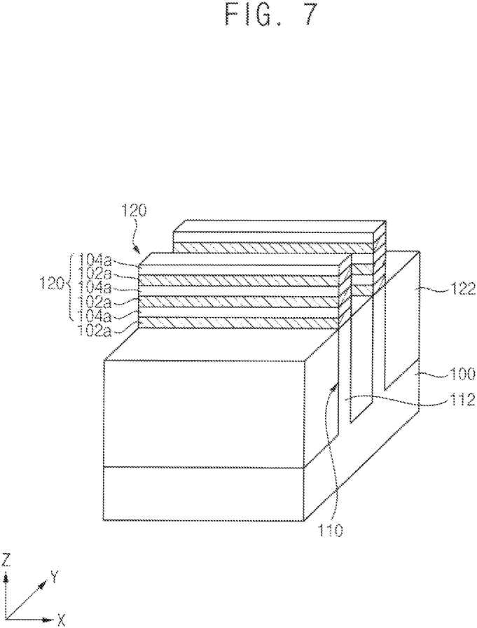

Referring to FIG. 7, an isolation layer filling the first trenches 110 may be formed. An upper portion of the isolation layer may be removed, so that an isolation pattern 122 covering a sidewall of the first active pattern 112 may be formed within the first trench. In addition, the mask pattern 106 may be removed.

The first fin structure 120 may protrude upward (e.g., in the third (Z) direction) between the isolation patterns 122. Therefore, a surface of the first fin structure 120 may be exposed.

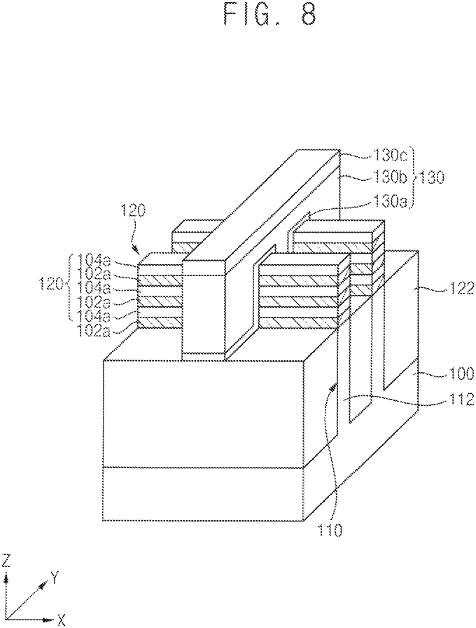

Referring to FIG. 8, a dummy gate structure 130 partially covering the isolation pattern 122 and the first fin structure 120 may be formed. The dummy gate structure 130 may extend in the second direction. Therefore, the dummy gate structure 130 may extend while traversing the first fin structure 120.

In detail, a dummy gate insulating layer, a dummy gate electrode layer, and a dummy gate mask layer may be sequentially formed on the first fin structure 120 and the isolation pattern 122, and first photoresist patterns (not shown) respectively extending in the second direction may be formed on the dummy gate mask layer. The dummy gate mask layer may be etched by using the first photoresist patterns so as to form dummy gate mask patterns 130c, respectively.

The dummy gate insulating layer may include, for example, an oxide such as a silicon oxide, the dummy gate electrode layer may include, for example, polysilicon, and the dummy gate mask layer may include, for example, a nitride such as a silicon nitride.

Thereafter, the dummy gate electrode layer and the dummy gate insulating layer formed on a lower portion of the dummy gate mask pattern 130c may be etched by using the dummy gate mask pattern 130c as an etching mask so as to form a dummy gate electrode 130b and a dummy gate insulating pattern 130a, respectively. The dummy gate structure 130 may include the dummy gate insulating pattern 130a, the dummy gate electrode 130b, and the dummy gate mask pattern 130c.

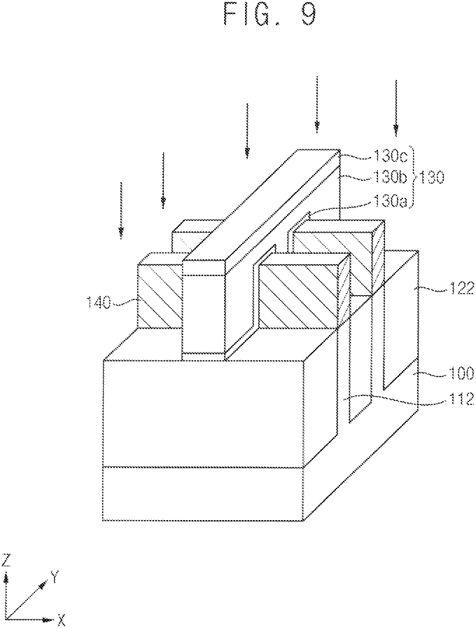

Referring to FIG. 9, the first fin structure 120 exposed on both sides of the dummy gate structure 130 may be doped with P-type impurities. In addition, the first fin structure 120 exposed on the both sides of the dummy gate structure 130 may be doped with germanium. The P-type impurities may include, for example, boron, gallium, or carbon. These may be used alone, or two or more of these may be used. Alternatively, the P-type impurities may include an element other than the above elements.

According to an exemplary embodiment, the doping of the P-type impurities may be performed at a concentration of 1E19 /cm³ to 1E22 /cm³. For example, the doping of the P-type impurities may be performed at a high concentration of 1E20 /cm³ to 1.5E21 /cm³. The doping process of the P-type impurities may include an ion implantation process.

When the doping of the P-type impurities is performed at a high concentration as described above, due to an impact caused by ion implantation (ion bombardment), lattices of the first silicon pattern 104a and the first silicon germanium pattern 102a, which are exposed, may be broken, and germanium atoms may be scattered. Accordingly, silicon and germanium in the first silicon pattern 104a and the first silicon germanium pattern 102a may be mixed with each other, so that the first fin structure 120 exposed on the both sides of the dummy gate structure 130 may be converted into a preliminary first source/drain layer 140 including silicon germanium.

The preliminary first source/drain layer 140 may be amorphized by the impurity doping. According to the exemplary embodiment, the preliminary first source/drain layer 140 may be formed of amorphous silicon germanium.

Meanwhile, a region of the first fin structure 120 covered by the dummy gate structure 130 may have a structure in which the first silicon germanium pattern 102a and the first silicon pattern 104a are stacked.

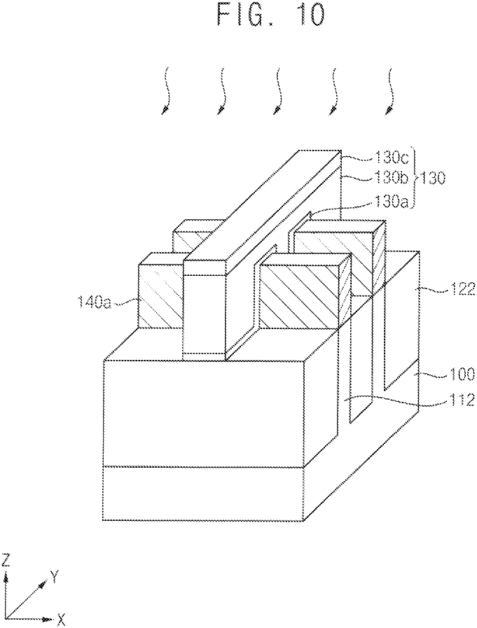

Referring to FIG. 10, an annealing process may be performed on the preliminary first source/drain layer 140, so that the preliminary first source/drain layer 140 may be converted into a first source/drain layer 140a including single crystal silicon germanium. The first source/drain layer 140a may be doped with the P-type impurities at a high concentration, so that the first source/drain layer 140a may serve as a source/drain of a PMOS transistor.

In detail, when the annealing process is performed, the preliminary first source/drain layer 140 may be recrystallized. Therefore, the amorphous silicon germanium may be converted into single crystal silicon germanium, so that the first source/drain layer 140a may be formed. In addition, when the annealing process is performed, the impurities in the preliminary first source/drain layer 140 may be activated.

According to the exemplary embodiment, the annealing process may include a nanosecond laser annealing process. The nanosecond laser annealing process may allow a temperature to be rapidly increased to a target temperature, so that a thermal budget may be reduced.

The nanosecond laser annealing process may be performed under an atmospheric pressure (about 1 atmosphere). The nanosecond laser annealing process may be performed at a temperature of 800 K to 2000 K in an air atmosphere. For example, a KrF laser, a XeCl laser, a neodymium: yttrium-aluminum-garnet (Nd:YAG) laser, and the like may be used as a laser source. A power density during the nanosecond laser annealing process may be 100 mJ/cm² to 1000 mJ/cm².

As described above, the ion implantation process of the P-type impurities and the annealing process may be performed on the first fin structure 120 exposed on the both sides of the dummy gate structure 130, so that the first source/drain layer 140a including single crystal silicon germanium may be formed on the both sides of the dummy gate structure 130. In addition, the region of the first fin structure 120 covered by the dummy gate structure 130 may be provided as a preliminary channel structure. The preliminary channel structure may have a structure in which the first silicon germanium pattern 102a and the first silicon pattern 104a are alternately stacked.

The first source/drain layer 140a may have the same sidewall profile as the first fin structure 120 formed by the patterning process. For example, the first source/drain layer 140a may have a vertical sidewall profile or a sidewall profile having an inclination when viewed in a sectional view in the second direction. A sidewall of the first source/drain layer 140a may not have a profile in which a portion protrudes. The first source/drain layer 140a may not have a polygonal shape in which a center portion protrudes (e.g., a partial shape of a pentagon, a hexagon, or a tetragon) when viewed in a sectional view in the second direction. For example, the width of the first source/drain layer 140a in the second direction is not greatest at the center portion of the first source/drain layer 140a. The width of the first source/drain layer 140a in the second direction may remain substantially the same along the third (Z) direction.

As described above, the first source/drain layer 140a may be formed through a simple process, and the first source/drain layer 140a may be doped with the P-type impurities at a high concentration.

In a general process, a recess may be formed by etching a region of the first fin structure corresponding to the first source/drain layer, and the first source/drain layer may be formed by performing a selective epitaxial growth process on an inside of the recess. In this case, crystal growth may be performed even in a lateral direction, so that the first source/drain layer may have a polygonal shape in which a center portion protrudes when viewed in a sectional view in the second direction. However, according to the method of the present embodiment, the first source/drain layer 140a of the PMOS transistor may be formed without performing the process of forming the recess and the selective epitaxial growth process.

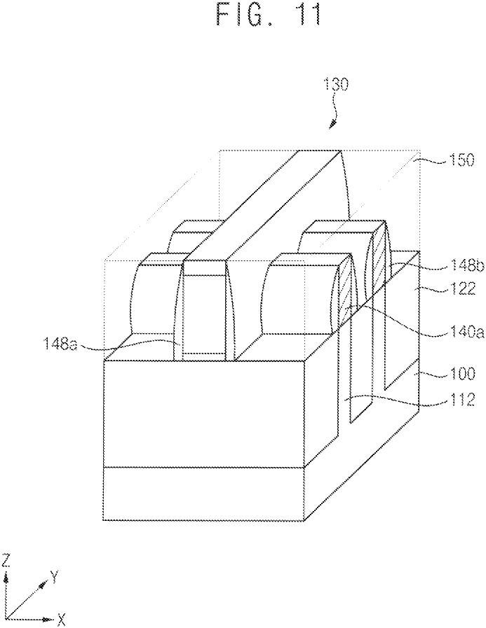

Referring to FIG. 11, first and second spacers 148a and 148b may be formed on sidewalls of the dummy gate structure 130 and the first source/drain layer 140a, respectively.

Since the first and second spacers 148a and 148b are formed after the first source/drain layer 140a is formed, the second spacer 148b may cover the sidewall of the first source/drain layer 140a in the second direction. In addition, a bottom surface of the first spacer 148a formed on the sidewall of the dummy gate structure 130 located on an uppermost first silicon pattern 104a may make contact with a top surface of the first source/drain layer 140a.

Thereafter, an interlayer insulating layer 150 covering the isolation pattern 122, the first source/drain layer 140a, the dummy gate structure 130, and the first and second spacers 148a and 148b may be formed. The interlayer insulating layer 150 may be planarized until a top surface of the dummy gate structure 130 is exposed. The planarization process may be performed by a chemical mechanical polishing (CMP) process and/or an etch-back process.

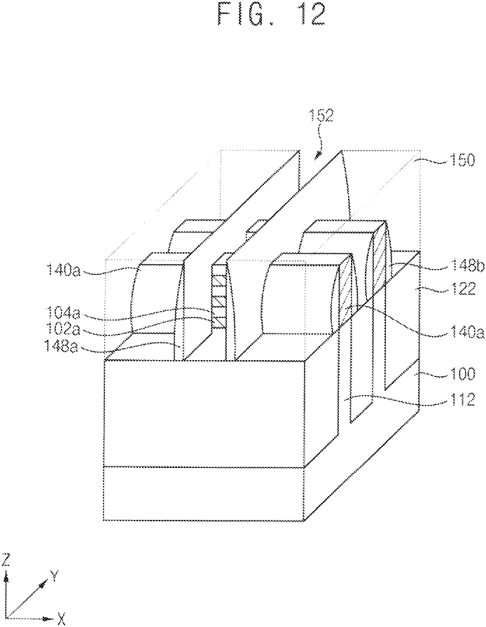

Referring to FIG. 12, the dummy gate structure 130 may be removed to form a first gate trench 152. The first silicon germanium pattern 102a and the first silicon pattern 104a of the preliminary channel structure may be exposed within the first gate trench 152.

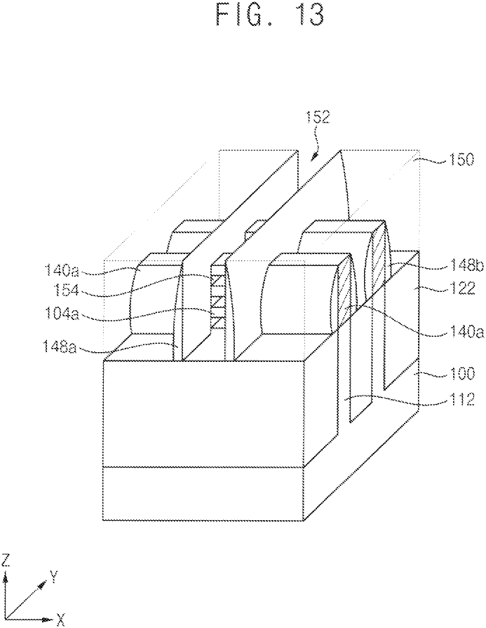

Referring to FIG. 13, the first silicon germanium pattern 102a exposed by the first gate trench 152 may be selectively removed to form gaps 154 between the first silicon patterns 104a. The first silicon patterns 104a may be provided as a channel region of the P-type MBC FET.

A gate structure 160 may be formed to fill the first gate trench 152 and the gaps 154 again. Therefore, the P-type MBC FET may be formed.

In detail, a thermal oxidation process may be performed on surfaces of the active pattern 112 and the first silicon patterns 104a exposed by the first gate trench 152 and the gaps 154 so as to form an interface layer, and a gate insulating layer may be formed on the interface layer. A gate electrode layer filling the first gate trench 152 and the gaps may be formed on the gate insulating layer. The gate electrode layer may include a metal material.

Thereafter, the gate electrode layer and the gate insulating layer may be planarized until a top surface of the interlayer insulating layer 150 is exposed. Upper portions of the gate electrode layer and the gate insulating layer may be partially removed, and a capping layer pattern may be formed in a region on which the removal is performed. Therefore, the gate structure 160 including an interface pattern (not shown), a gate insulating pattern 160a, a gate electrode 160b, and a capping pattern 160c may be formed, as illustrated, for example, in FIG. 1.

The semiconductor device may be completed through the above processes.

Hereinafter, a semiconductor device including a P-type MBC FET and an N-type MBC FET will be described.

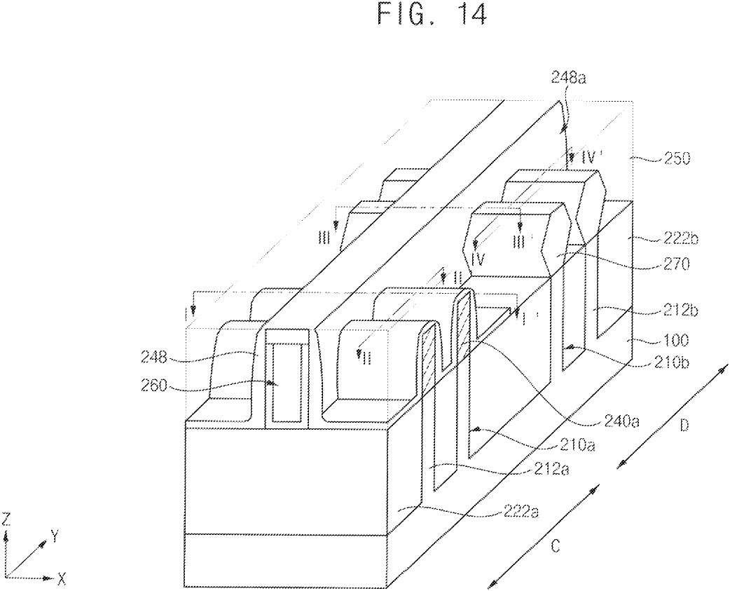

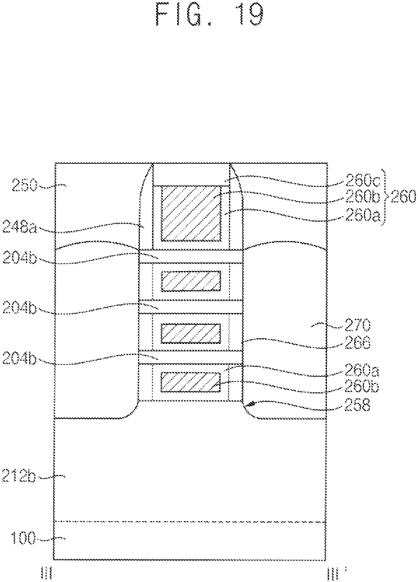

FIGS. 14 to 18 are perspective and sectional views for describing a semiconductor device according to exemplary embodiments. FIG. 19 is a sectional view showing a semiconductor device according to some exemplary embodiments.

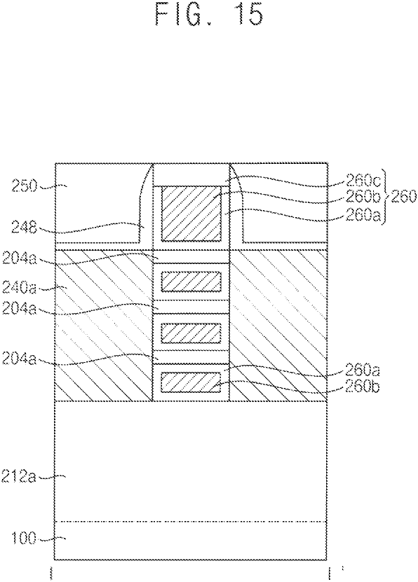

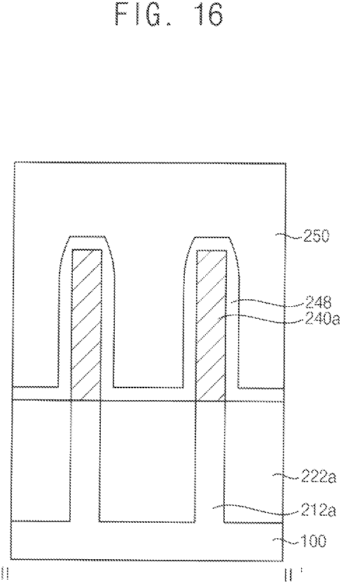

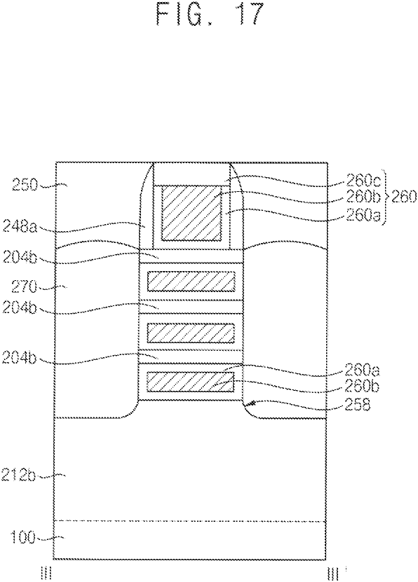

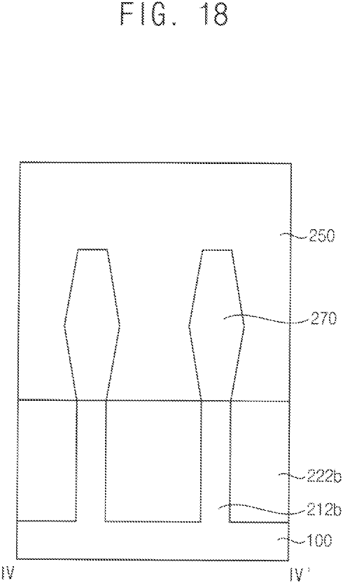

In detail, FIG. 14 is a perspective view, FIGS. 15 and 16 are sectional views taken along lines I-I′ and II-II′ of FIG. 14, respectively, and FIGS. 17 and 18 are sectional views taken along lines III-III′ and IV-IV′ of FIG. 14, respectively. FIGS. 15 and 16 show a P-type MBC FET, and FIGS. 17 and 18 show an N-type MBC FET. FIG. 19 is a sectional view taken along the line IV-IV′ of FIG. 14.

Referring to FIGS. 14 to 18, the semiconductor device may include a P-type MBC FET formed on a first region (C) of a substrate, and an N-type MBC FET formed on a second region (D) of the substrate.

FIG. 14 shows a P-type MBC FET and an N-type MBC FET, which share one gate structure 260 as a common gate. However, the concept of the present disclosure is not limited thereto, and the P-type MBC FET and the N-type MBC FET may be spaced apart from each other in the first direction so that the P-type MBC FET and the N-type MBC FET may include separate gate structures, respectively.

The P-type MBC FET may include a first active pattern 212a, a gate structure 260, first silicon patterns 204a, a first source/drain layer 240a, a spacer layer 248, and a first isolation pattern 222a.

The N-type MBC FET may include a second active pattern 212b, a gate structure 260, second silicon patterns 204b, a second source/drain layer 270, a first spacer 248a, and a second isolation pattern 222b. In addition, each of the P-type MBC FET and the N-type MBC FET may further include an interlayer insulating layer 250.

The gate structure 260 formed on the first region may be provided as a first gate structure that is a gate of the P-type MBC FET. The gate structure 260 formed on the second region may be provided as a second gate structure that is a gate of the N-type MBC FET.

The P-type MBC FET may be substantially the same as the P-type MBC FET described with reference to FIGS. 1 to 4 except for the spacer layer 248. The spacer layer 248 may cover the first isolation pattern 222a, a sidewall of the gate structure 260, and the first source/drain layer 240a on the first region of the substrate.

In some exemplary embodiments, as described with reference to FIGS. 1 to 4, a spacer may be formed on the sidewall of the gate structure and a sidewall of the first source/drain layer. Therefore, the P-type MBC FET may have the same structure as the P-type MBC FET described with reference to FIGS. 1 to 4.

With regard to the P-type MBC FET, as described with reference to FIGS. 1 to 4, the first source/drain layer 240a may include single crystal silicon germanium. The first source/drain layer 240a may be doped with P-type impurities. The P-type impurities may include, for example, boron, gallium, or carbon. These may be used alone, or two or more of these may be used. According to an exemplary embodiment, the P-type impurities may have a concentration of 1E19 /cm³ to 1E22 /cm³. For example, the P-type impurities may have a high concentration of 1E20 /cm³ to 1.5E21 /cm³. Accordingly, the first source/drain layer 240a may serve as a source/drain layer of a PMOS transistor.

The first source/drain layer 240a may have a sidewall profile formed through an anisotropic etching process. Since the first source/drain layer 240a is not formed through a selective epitaxial growth process, the first source/drain layer 240a may have a sidewall profile that is different from a sidewall profile of a layer formed through the selective epitaxial growth process.

According to the exemplary embodiment, as shown in FIG. 16, the first source/drain layer 240a may have a vertical sidewall profile when viewed in a sectional view in the second direction. In some exemplary embodiments, as shown in FIG. 4, the first source/drain layer may have a sidewall profile having an inclination that allows a width to be gradually increased downward (e.g., along the third (Z) direction toward the first active pattern 212a) when viewed in a sectional view in the second direction.

A top surface of the first source/drain layer 240a and a top surface of the first silicon pattern 204a located at an uppermost portion may be located on the same plane. The top surface of the first source/drain layer 240a and the top surface of the first silicon pattern 204a located at the uppermost portion may not have a separate boundary or step with respect to each other.

In the first region, the sidewall of the gate structure 260 disposed between the first silicon patterns 204a or between the first silicon pattern 204a and the first active pattern 212a may be in contact with the first source/drain layer 240a. According to the exemplary embodiment, an inner spacer may not be provided between the sidewall of the gate structure 260 and the first source/drain layer 240a.

Hereinafter, the N-type MBC FET formed in the second region of the substrate will be described.

The second active pattern 212b may be formed by etching a portion of the second region of the substrate 100. The second active pattern 212b may have a shape protruding from an upper portion of the substrate 100. A second trench 210b may be provided on both sides of the second active pattern 212b. According to exemplary embodiments, the second active pattern 212b may extend in the first direction X. A plurality of second active patterns 212b may be arranged in parallel to each other while being spaced apart from each other in the second direction Y.

According to the exemplary embodiment, the second active patterns 212b may be arranged in parallel to the first active pattern 212a in the second direction. According to the exemplary embodiment, although not shown, the second active patterns 212b may be spaced apart from the first active pattern 212a in the first direction.

The second isolation pattern 222b may be provided within the second trench 210b on the both sides of the second active pattern 212b.

A plurality of second silicon patterns 204b spaced apart from each other in the vertical direction from a top surface of the second active pattern 212b may be provided. The second silicon patterns 204b may be provided as channels of the N-type MBC FET. The second silicon patterns 204b may include single crystal silicon.

The second source/drain layer 270 may extend in the vertical direction from the top surface of the second active pattern 212b, and may be in contact with sidewalls of the second silicon patterns 204b in the first direction, in which the second silicon patterns 204b are spaced apart from each other in the vertical direction. Therefore, the sidewalls of the second silicon patterns 204b may be in contact with the second source/drain layer 270.

A space defined by the second source/drain layer 270 and a region in which the second silicon patterns 204b are spaced apart from each other in the vertical direction will be referred to as a second gap.

The gate structure 260 may be formed on the first and second isolation patterns 222a and 222b, the first active pattern 212a, and the second active pattern 212b, and may extend in the second direction while filling the first gap and the second gap. In other words, the first gate structure on the first region may extend in the second direction while filling the first gap. The second gate structure on the second region may extend in the second direction while filling the second gap. The gate structure 260 may cover the first silicon patterns 204a and the second silicon patterns 204b.

Meanwhile, one gate structure 260 has been shown in the drawings as being formed on the substrate 100. In other words, ends of the first gate structure of the P-type MBC FET and the second gate structure of the N-type MBC FET may be connected to each other so that the first gate structure of the P-type MBC FET and the second gate structure of the N-type MBC FET may be provided as one common gate structure. However, the concept of the present disclosure is not limited thereto, and a plurality of gate structures spaced apart from each other in the first direction may be formed. Although not shown, the P-type MBC FET and the N-type MBC FET may include separate first and second gate structures, respectively, without using the common gate structure.

The first spacer 248a may be provided on the sidewall of the gate structure 260 on the second region of the substrate.

A sidewall of the second silicon pattern 204b in the first direction may be located vertically downward (e.g., along the third (Z) direction) from a sidewall profile of the first spacer 248a. In addition, the second source/drain layer 270 may be formed on a lateral side of the first spacer 248a. Therefore, the second silicon pattern 204a may be located directly under a bottom surface of the first spacer 248a, while the second source/drain layer 270 may not be located directly under the bottom surface of the first spacer 248a.

The second source/drain layer 270 may include single crystal silicon. The second source/drain layer 270 may be doped with N-type impurities. The N-type impurities may include, for example, phosphorus, arsenic, or antimony. These may be used alone, or two or more of these may be used. Alternatively, the N-type impurities may include an element other than the above elements. Accordingly, the second source/drain layer 270 may serve as a source/drain layer of an NMOS transistor.

The second source/drain layer 270 may be formed through an etching process for forming a recess and a selective epitaxial growth process in the formed recess. Since the second source/drain layer 270 is formed by growing in the vertical direction and a lateral direction, a sidewall of the second source/drain layer in the second direction may have a profile in which a portion protrudes. For example, the sidewall in the second direction of the second source/drain layer 270 may be configured such that upper and lower portions of the sidewall are connected to each other at an oblique angle to allow a center portion of the sidewall of the second source/drain layer 270 to protrude. The second source/drain layer 270 may have a polygonal shape in which a center portion protrudes (e.g., a partial shape of a pentagon, a hexagon, or a tetragon) when viewed in a sectional view in the second direction. As described above, when viewed in a sectional view in the second direction, the second source/drain layer 270 may have a sidewall profile that is different from a sidewall profile of the first source/drain layer 240a.

A position of a bottom surface of the second source/drain layer 270 may be determined in the etching process for forming the recess. Therefore, the bottom surface of the second source/drain layer 270 may not be located on the same plane as a bottom surface of the gate structure 260. When the recess is formed, an upper portion of the second active pattern 212b may also be partially etched by excessive etching. In this case, the bottom surface of the second source/drain layer 270 may be located lower than the bottom surface of the gate structure 260 that is adjacent to the second source/drain layer 270.

A top surface of the second source/drain layer 270 may be determined by the selective epitaxial growth process. Therefore, the top surface of the second source/drain layer 270 may not be located on the same plane as a top surface of the second silicon pattern 204b. During the selective epitaxial growth process, the second source/drain layer 270 may be located higher than an uppermost second silicon pattern 204b. In this case, the top surface of the second source/drain layer 270 may be located higher than the top surface of the second silicon pattern 204b.

According to the exemplary embodiment, a spacer may not be provided on the sidewall of the second source/drain layer 270 in the second direction. In some exemplary embodiments, a spacer covering a lower portion of the sidewall of the second source/drain layer 270 in the second direction may be provided. Therefore, when viewed in a sectional view in the second direction, at least a portion of the sidewall of the second source/drain layer 140a may not be covered by the spacer.

In some exemplary embodiments, as shown in FIG. 19, an inner spacer 266 may be further provided on both sidewalls of the second gap. The inner spacer 266 may be interposed between the second source/drain layer 270 and the sidewall of the gate structure. Therefore, the inner spacer may be in contact with each of the sidewalls of the second source/drain layer 270 and the gate structure 260.

The interlayer insulating layer 250 covering the first and second isolation patterns 222a and 222b, the first source/drain layer 240a, the second source/drain layer 270, the spacer layer 248, and the first spacer 248a may be provided. A top surface of the interlayer insulating layer 250 may be located on the same plane as a top surface of the gate structure 260. Therefore, the interlayer insulating layer 250 may cover the sidewall of the gate structure 260.

The semiconductor device may include a P-type MBC FET and an N-type MBC FET having target electrical characteristics.

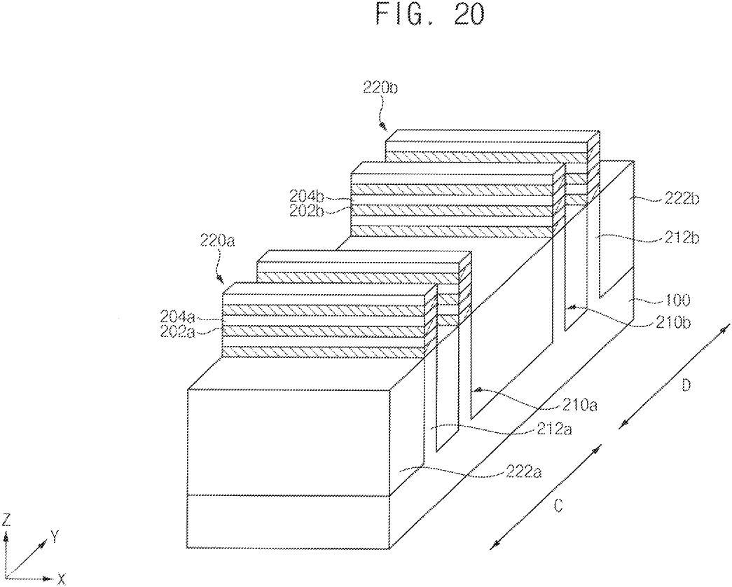

FIGS. 20 to 28 are sectional views for describing a method of manufacturing a semiconductor device according to exemplary embodiments.

Referring to FIG. 20, a silicon germanium layer and a silicon layer may be alternately and repeatedly stacked on a substrate 100 including first and second regions (C and D). First and second mask patterns may be formed on an uppermost silicon layer located in the first region and the second region, respectively.

First and second trenches 210a and 210b may be formed on the first and second regions of the substrate 100, respectively, by etching the silicon germanium layer, the silicon layer, and an upper portion of the substrate 100 by using the first and second mask patterns as etching masks.

Accordingly, first active patterns 212a extending in the first direction may be formed on the first region of the substrate 100, and a first fin structure 220a including first silicon germanium patterns 202a and first silicon patterns 204a, which are alternately and repeatedly stacked, may be formed on each of the first active patterns 212a. The first fin structures 220a may be arranged in parallel to each other while being spaced apart from each other in the second direction.

In addition, second active patterns 212b extending in the first direction may be formed on the second region of the substrate 100, and a second fin structure 220b including second silicon germanium patterns 202b and second silicon patterns 204b, which are alternately and repeatedly stacked, may be formed on each of the second active patterns 212b. The second fin structures 220b may be arranged in parallel to each other while being spaced apart from each other in the second direction.

An isolation layer filling the first and second trenches 210a and 210b may be formed. An upper portion of the isolation layer may be removed, so that first and second isolation patterns 222a and 222b covering sidewalls of the first and second active patterns 212a and 212b may be formed within the first and second trenches 210a and 210b, respectively. In addition, the first and second mask patterns may be removed. Therefore, surfaces of the first and second fin structures 220a and 220b may be exposed.

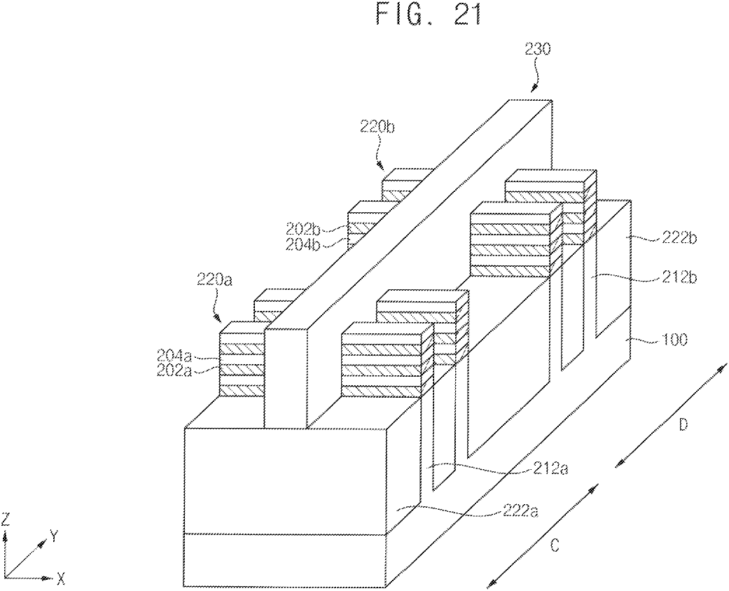

Referring to FIG. 21, a dummy gate structure 230 partially covering the first and second isolation patterns 222a and 222b, the first fin structure 220a, and the second fin structure 220b may be formed. The dummy gate structure 230 may extend in the second direction. Although not shown, the dummy gate structure may include a dummy gate insulating pattern, a dummy gate electrode, and a dummy gate mask pattern.

According to an exemplary embodiment, the first fin structures 220a and the second fin structures 220b may be arranged in parallel to each other while being spaced apart from each other in the second direction. In addition, the dummy gate structure 230 may extend in the second direction while covering both the first fin structures 220a and the second fin structures 220b.

In some exemplary embodiments, the second fin structures 220b may be spaced apart from the first fin structures 220a in the first direction. In this case, a first dummy gate structure partially covering the first fin structures 220a and a second dummy gate structure partially covering the second fin structures 220b may be formed, respectively.

The dummy gate structure 230 may include a dummy gate insulating pattern, a dummy gate electrode, and a dummy gate mask pattern.

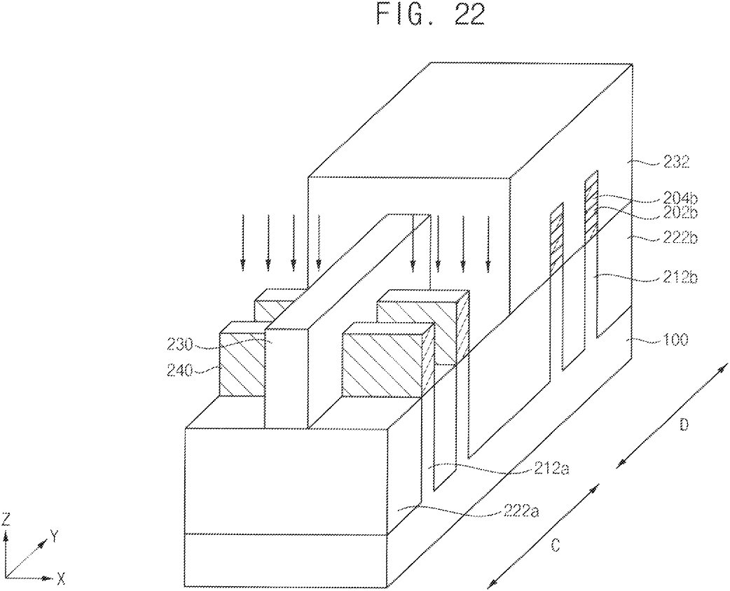

Referring to FIG. 22, a third mask pattern 232 covering the second region of the substrate 100 may be formed. According to the exemplary embodiment, the third mask pattern 232 may include a photoresist pattern. The second isolation pattern 222b, the dummy gate structure 230, and the second fin structure 220b formed on the second region of the substrate 100 may be covered by the third mask pattern 232.

In the first region of the substrate 100, the first fin structure 220a exposed on both sides of the dummy gate structure 230 may be doped with P-type impurities. In addition, the first fin structure 220a exposed on the both sides of the dummy gate structure 230 may be doped with germanium. The P-type impurities may include, for example, boron, gallium, or carbon.

According to the exemplary embodiment, the doping of the P-type impurities may be performed at a concentration of 1E19 /cm³ to 1E22 /cm³. The doping process of the P-type impurities may include an ion implantation process. The impurity doping process may be the same as the impurity doping process described with reference to FIG. 9.

As the impurity doping process is performed, silicon and germanium in a first silicon pattern 204a and a first silicon germanium pattern 202a of the first fin structure 220a exposed on the both sides of the dummy gate structure may be mixed with each other. Therefore, in the first region of the substrate 100, a preliminary first source/drain layer 240 including amorphous silicon germanium may be formed on the both sides of the dummy gate structure 230.

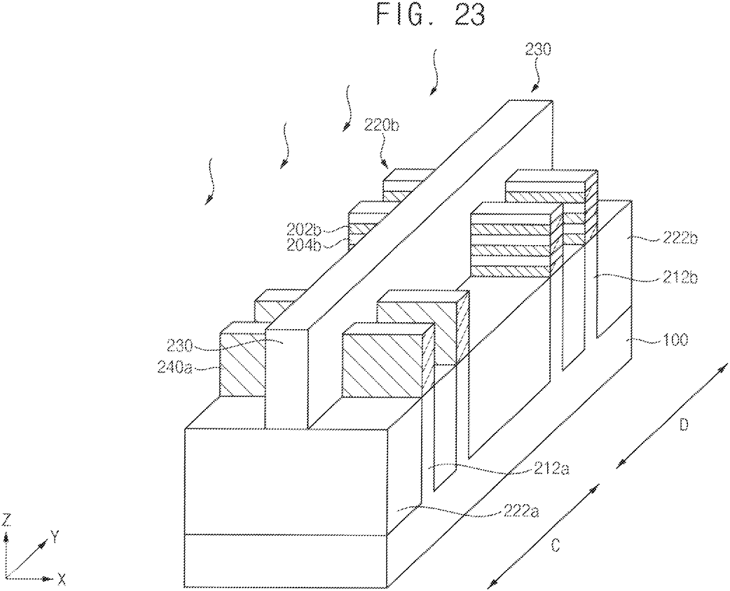

Referring to FIG. 23, the third mask pattern 232 may be removed.

An annealing process may be performed on the preliminary first source/drain layer 240 exposed in the first region of the substrate 100, so that the preliminary first source/drain layer 240 may be converted into a first source/drain layer 240a including single crystal silicon germanium. The first source/drain layer 240a may be provided as a source/drain of a PMOS transistor. The annealing process may be the same as the annealing process described with reference to FIG. 10.

When the annealing process is performed, the P-type impurities in the preliminary first source/drain layer 240 may be activated. According to the exemplary embodiment, the annealing process may include a nanosecond laser annealing process.

A region of the first fin structure 220a covered by the dummy gate structure 230 may be provided as a preliminary first channel structure. The preliminary first channel structure may have a structure in which the first silicon germanium pattern 202a and the first silicon pattern 204a are alternately stacked.

The first source/drain layer 240a may have the same sidewall profile as the first fin structure 220a patterned through an anisotropic etching process. For example, the first source/drain layer 240a may have a vertical sidewall profile or a sidewall profile having an inclination that allows a width to be gradually increased downward (e.g., along the third (Z) direction toward the first active pattern 212a) when viewed in a sectional view in the second direction. For example, when viewed in a sectional view in the second direction, the sidewall of the first source/drain layer 240a may have a constant inclination with respect to a top surface of the substrate. A variation rate of a thickness of the first source/drain layer 240a in the second direction may be constant from a top to a bottom of the first source/drain layer 240a.

The sidewall of the first source/drain layer 240a in the second direction may not have a profile in which a portion protrudes. The first source/drain layer 240a may not have a polygonal shape in which a center portion protrudes (e.g., a partial shape of a pentagon, a hexagon, or a tetragon) when viewed in a sectional view in the second direction. The sidewall of the first source/drain layer 240a in the second direction may be flat (e.g., substantially planar). For example, the width of the first source/drain layer 240a in the second direction is not greatest at the center portion of the first source/drain layer 240a. The width of the first source/drain layer 240a in the second direction may remain substantially the same along the third (Z) direction. In an alternative, the width of the first source/drain layer 240a in the second direction may taper from one end of the first source/drain layer 240a to another end of the first source/drain layer 240a along the third (Z) direction.

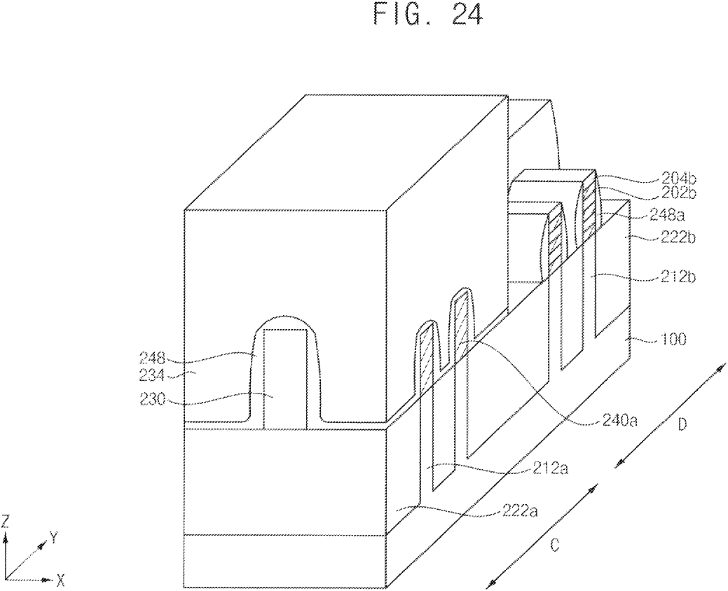

Referring to FIG. 24, a preliminary spacer layer may be formed on surfaces of the dummy gate structure 230, the first source/drain layer 240a, and the second fin structure 220b.

A fourth mask pattern 234 covering the first region of the substrate 100 may be formed. According to the exemplary embodiment, the fourth mask pattern 234 may include a photoresist pattern.

The preliminary spacer layer formed on the second region may be anisotropically etched. Accordingly, a first spacer 248a may be formed on sidewalls of the dummy gate structure 230 and the second fin structure 220b formed in the second region. In addition, since the fourth mask pattern 234 is formed on the first region, the preliminary spacer layer may remain on the first region, and the preliminary spacer layer formed on the first region may be formed as a spacer layer 248. The spacer layer may cover the surfaces of the dummy gate structure 230 and the first source/drain layer 240a formed in the first region.

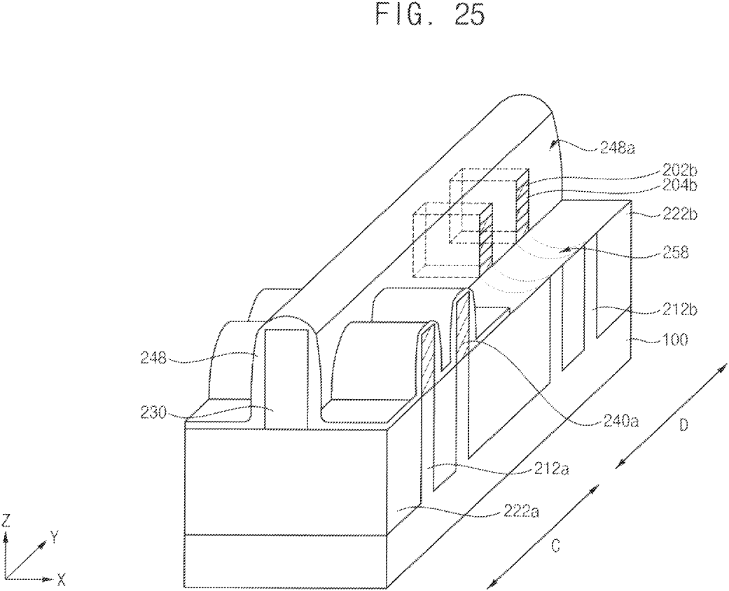

Referring to FIG. 25, the second fin structure 220b that is exposed may be etched by using the dummy gate structure 230, the first spacer 248a, and the spacer layer 248 as etching masks, so that a first recess 258 exposing a top surface of the second active pattern 212b of the substrate 100 may be formed. The first recess 258 may be formed only in the second fin structure 220b.

During the etching process for forming the first recess 258, at least a portion of the first spacer 248a located at an end of the first recess 258 in the second direction may be removed. According to the exemplary embodiment, the entire first spacer 248a located at the end of the first recess 258 in the second direction may be removed. In some exemplary embodiments, although not shown, a portion of the first spacer located at the end of the first recess 258 in the second direction may be removed so that the first spacer may remain only in a lower portion of the first recess 258.

In some exemplary embodiments, although not shown, a second recess (not shown) may be formed by etching a portion of a sidewall of a second silicon germanium pattern 202b exposed by a sidewall of the first recess 258 in the first direction, and the second recess may be filled with an insulating material. Therefore, an inner spacer (see 266 in FIG. 19) may be formed on both sides of the second silicon germanium pattern 202b. In this case, processes may be subsequently performed, so that a semiconductor device having a section as shown in FIG. 19 may be manufactured through a subsequent process.

Thereafter, the fourth mask pattern 234 may be removed.

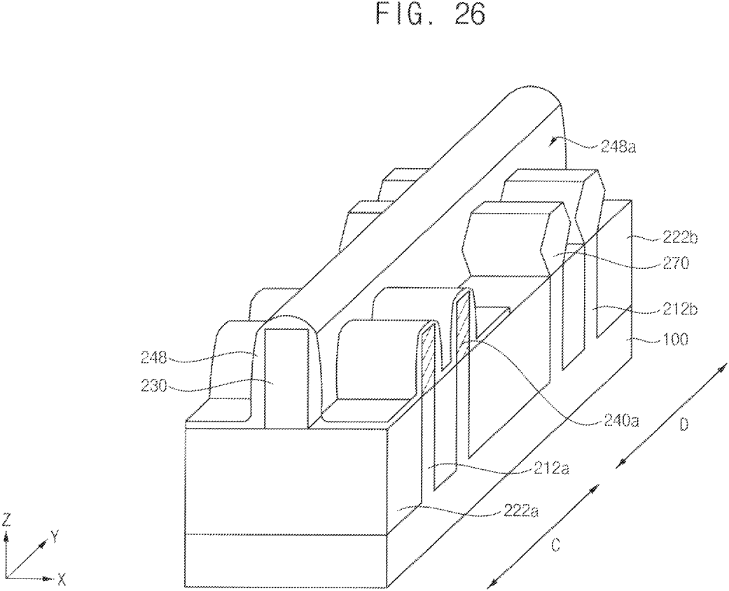

Referring to FIG. 26, a second source/drain layer 270 may be formed on the top surface of the second active pattern 212b exposed by the first recess 258.

According to the exemplary embodiment, the second source/drain layer 270 may be formed by performing a selective epitaxial growth process using surfaces of the second active pattern 212b, the second silicon pattern 204b, and the second silicon germanium pattern 202b exposed by the first recess 258 as seeds. The second source/drain layer 270 may be formed of single crystal silicon. When the selective epitaxial growth process is performed, N-type impurities may be doped in situ. Therefore, the second source/drain layer 270 may serve as a source/drain of an NMOS transistor.

According to the exemplary embodiment, the selective epitaxial growth process may be performed, for example, by using a silicon source gas such as a disilane (Si₂H₆) gas, so that a single crystal silicon layer may be formed. Alternatively, the selective epitaxial growth process may be performed, for example, by using a carbon source gas such as a SiH₃CH₃ gas, so that a single crystal silicon carbide (SiC) layer may be formed.

The second source/drain layer 270 may be formed by growing in the vertical direction and the lateral direction. Therefore, a sidewall of the second source/drain layer 270 in the second direction may have a profile in which a portion protrudes. For example, the second source/drain layer 270 may have a polygonal shape in which a center portion protrudes (e.g., a partial shape of a pentagon, a hexagon, or a tetragon) when viewed in a sectional view in the second direction. As described above, the second source/drain layer 270 may have a sidewall profile that is different from a sidewall profile of the first source/drain layer 240a.

A region of the second fin structure 220b covered by the dummy gate structure 230 may be provided as a preliminary second channel structure. The preliminary second channel structure may have a structure in which the second silicon germanium pattern 202b and the second silicon pattern 204b are alternately stacked.

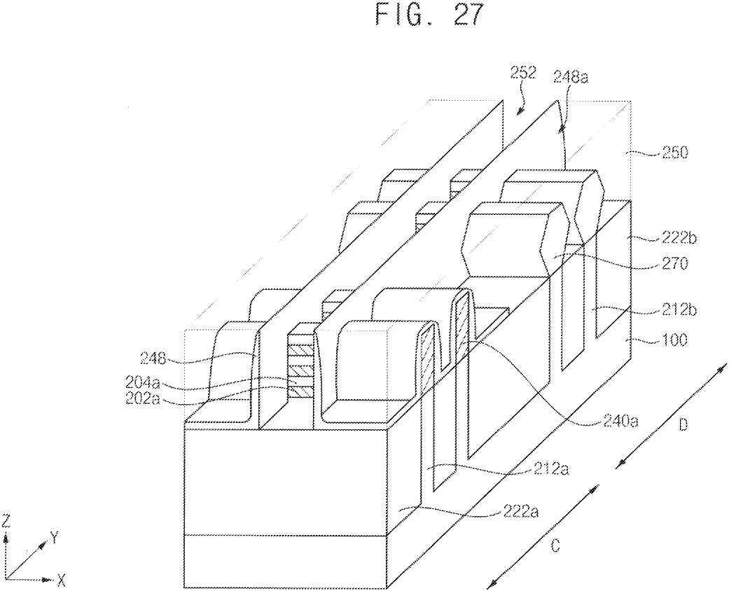

Referring to FIG. 27, an interlayer insulating layer 250 covering the first and second isolation patterns 222a and 222b, the first source/drain layer 240a, the second source/drain layer 270, the dummy gate structure 230, the spacer layer 248, and the first spacer 248a on the first and second regions of the substrate 100 may be formed. The interlayer insulating layer 250 may be planarized until a top surface of the dummy gate structure 230 is exposed. The planarization process may be performed by a chemical mechanical polishing (CMP) process and/or an etch-back process.

The dummy gate structure 230 may be removed to form a gate trench 252. The first silicon germanium pattern 202a and the first silicon pattern 204a of the preliminary first channel structure and the second silicon germanium pattern 202b and the second silicon pattern 204b of the preliminary second channel structure may be exposed within the gate trench 252.

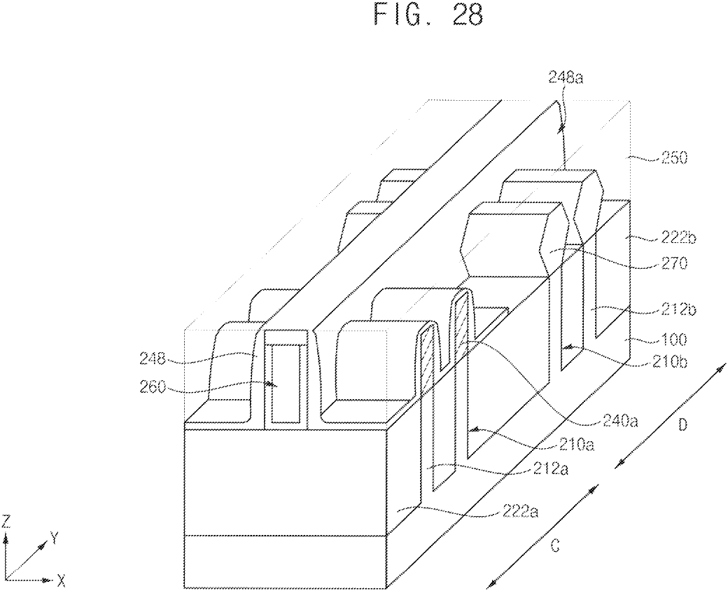

Referring to FIG. 28, the first and second silicon germanium patterns 202a and 202b exposed by the gate trench 252 may be removed to form first gaps between the first silicon patterns 204a and form second gaps between the second silicon patterns 204b.

A gate structure 260 may be formed to fill the gate trench 252 and the first and second gaps again. Therefore, the P-type MBC FET may be formed on the first region, and the N-type MBC FET may be formed on the second region.

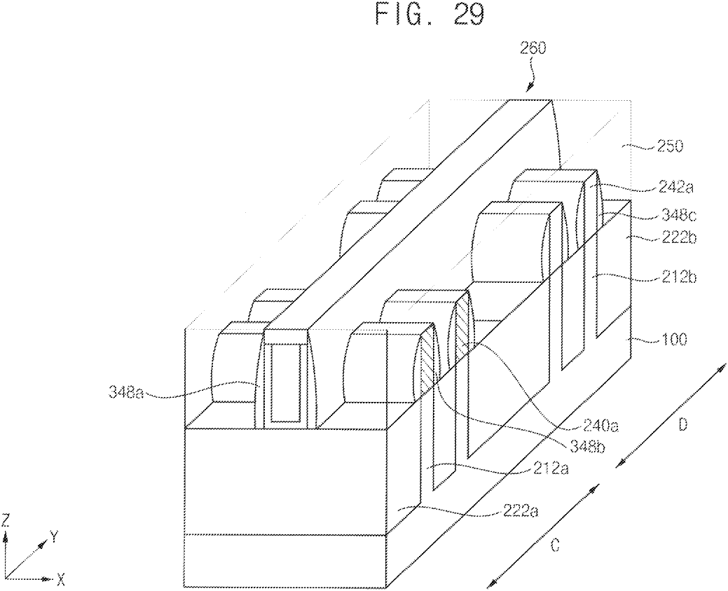

FIGS. 29 to 33 are perspective and sectional views for describing a semiconductor device according to exemplary embodiments.

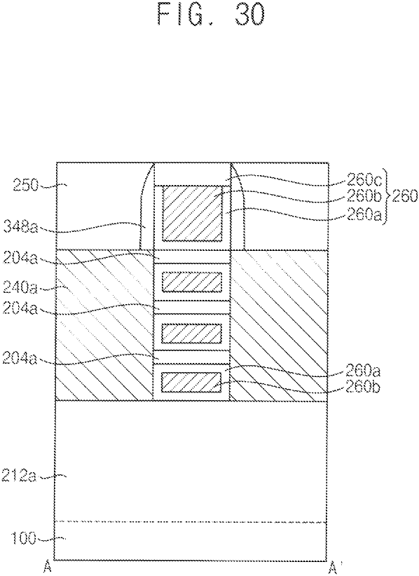

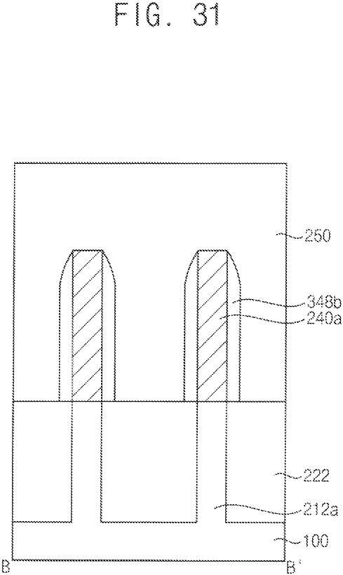

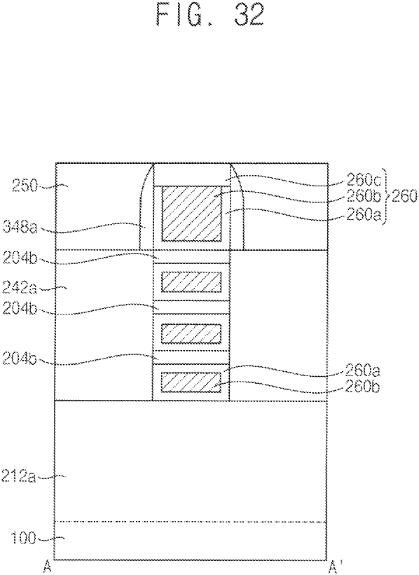

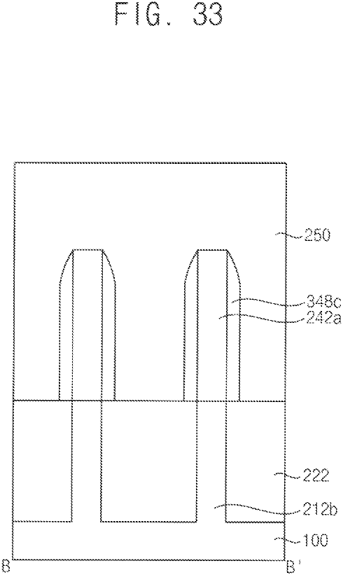

In detail, FIG. 29 is a perspective view, FIGS. 30 and 31 are sectional views taken along lines I-I′ and II-II′ of FIG. 29, respectively, and FIGS. 32 and 33 are sectional views taken along lines III-III′ and IV-IV′ of FIG. 29, respectively. FIGS. 30 and 31 show a P-type MBC FET, and FIGS. 32 and 33 show an N-type MBC FET.

Referring to FIGS. 29 to 33, the semiconductor device may include a P-type MBC FET formed on a first region (C) of a substrate, and an N-type MBC FET formed on a second region (D) of the substrate.

The P-type MBC FET may include a first active pattern 212a, a gate structure 260, first silicon patterns 204a, a first source/drain layer 240a, first and second spacers 348a and 348b, and a first isolation pattern 222a.

The N-type MBC FET may include a second active pattern 212b, a gate structure 260, second silicon patterns 204b, a second source/drain layer 242a, first and third spacers 348a and 348c, and a second isolation pattern 222b. In addition, each of the P-type MBC FET and the N-type MBC FET may further include an interlayer insulating layer 250.

The P-type MBC FET may be substantially the same as the P-type MBC FET described with reference to FIGS. 14 to 16 except for a spacer. The P-type MBC FET may be substantially the same as the P-type MBC FET described with reference to FIGS. 1 to 4.

In other words, the P-type MBC FET may be configured such that the first spacer 348a is formed on a sidewall of the gate structure 260, and the second spacer 348b is formed on a sidewall of the first source/drain layer 240a.

The N-type MBC FET may be identical or similar to the N-type MBC FET described with reference to FIGS. 14, 17, and 19 except for the second source/drain layer 242a. Therefore, the second source/drain layer 242a will be mainly described.

The second source/drain layer 242a may extend in the vertical direction from the top surface of the second active pattern 212b, and may be in contact with sidewalls of the second silicon patterns 204b in the first direction, in which the second silicon patterns 204b are spaced apart from each other in the vertical direction. Therefore, the sidewalls of the second silicon patterns 204b may be in contact with the second source/drain layer 242a.

The second source/drain layer 242a may be silicon including germanium. A concentration of germanium included in the second source/drain layer 242a may be less than a concentration of germanium included in the first source/drain layer 240a. The second source/drain layer 242a may be doped with N-type impurities. Accordingly, the second source/drain layer 242a may serve as a source/drain layer of an NMOS transistor.

The second source/drain layer 242a may have a sidewall profile formed through an anisotropic etching process. Since the second source/drain layer 242a is not formed through a selective epitaxial growth process, the second source/drain layer 242a may have a sidewall profile that is different from a sidewall profile of a layer formed through the selective epitaxial growth process. The second source/drain layer 242a may have a vertical sidewall profile or a sidewall profile having an inclination that allows a width to be gradually increased downward (e.g., along the third (Z) direction) when viewed in a sectional view in the second direction. For example, when viewed in a sectional view in the second direction, the sidewall of the second source/drain layer 242a may have a constant inclination with respect to a top surface of the substrate. A variation rate of a thickness of the second source/drain layer 242a in the second direction may be constant from a top to a bottom of the second source/drain layer 242a.

For example, the sidewall of the second source/drain layer 242a in the second direction may not have a profile in which a portion protrudes. As described above, the first and second source/drain layers 240a and 242a may not have a polygonal shape in which a center portion protrudes (e.g., a partial shape of a pentagon, a hexagon, or a tetragon) when viewed in a sectional view in the second direction. For example, the width of the first and second source/drain layers 240a and 242a in the second direction is not greatest at the center portion of the first and second source/drain layers 240a and 242a. The width of the first and second source/drain layers 240a and 242a in the second direction may remain substantially the same along the third (Z) direction.

According to an exemplary embodiment, a top surface of the second source/drain layer 242a and a top surface of the second silicon pattern 204b located at an uppermost portion may be located on the same plane. The top surface of the second source/drain layer 242a and the top surface of the second silicon pattern 204b located at the uppermost portion may not have a separate boundary or step with respect to each other.

According to the exemplary embodiment, a bottom surface of the second source/drain layer 242a may be located on the same plane as a lowermost surface of the gate structure 260 that is adjacent to the second source/drain layer 242a.

The third spacer 348c may be provided on the sidewall of the second source/drain layer 242a. The third spacer 348c may cover the sidewall of the second source/drain layer 242a in the second direction. Therefore, when viewed in a sectional view in the second direction, the third spacer 348c may completely cover the sidewall of the second source-drain layer 270.

According to the exemplary embodiment, a bottom surface of the third spacer 348c formed on the sidewall of the gate structure 260 located on the uppermost second silicon pattern 204b may make contact with the top surface of the second source/drain layer 242a.

The sidewall of the gate structure 260 in the second region may be in contact with the second source/drain layer.

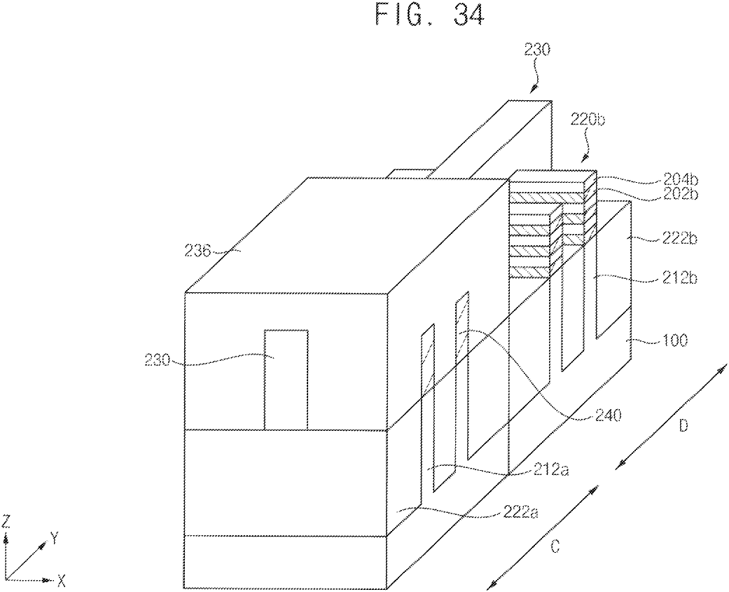

FIGS. 34 to 37 are perspective and sectional views for describing a semiconductor device according to exemplary embodiments.

Processes that are identical or similar to the processes described with reference to FIGS. 20 to 22 may be performed. Therefore, a structure shown in FIG. 22 may be formed.

Referring to FIG. 34, a fourth mask pattern 236 covering the first region of the substrate 100 may be formed. According to an exemplary embodiment, the fourth mask pattern 236 may include a photoresist pattern.

The second fin structure 220b exposed in the second region of the substrate 100 may be doped with N-type impurities. In addition, the second fin structure 220b exposed in the second region of the substrate 100 may be further doped with silicon. The N-type impurities may include, for example, phosphorus, arsenic, or antimony. These may be used alone, or two or more of these may be used. Alternatively, the N-type impurities may include an element other than the above elements.

According to the exemplary embodiment, the doping process of the N-type impurities may include an ion implantation process.

As the impurity doping process is performed, silicon and germanium in the second silicon pattern 204b and the second silicon germanium pattern 202b exposed on the both sides of the dummy gate structure 230 may be mixed with each other, so that a preliminary second source/drain layer 242 including silicon germanium may be formed. A concentration of germanium included in the preliminary second source/drain layer 242 may be less than a concentration of germanium included in the preliminary first source/drain layer 240. In other words, the preliminary second source/drain layer 242 may be provided as a silicon layer including germanium.

After the doping of the impurities is performed, the fourth mask pattern 236 may be removed.

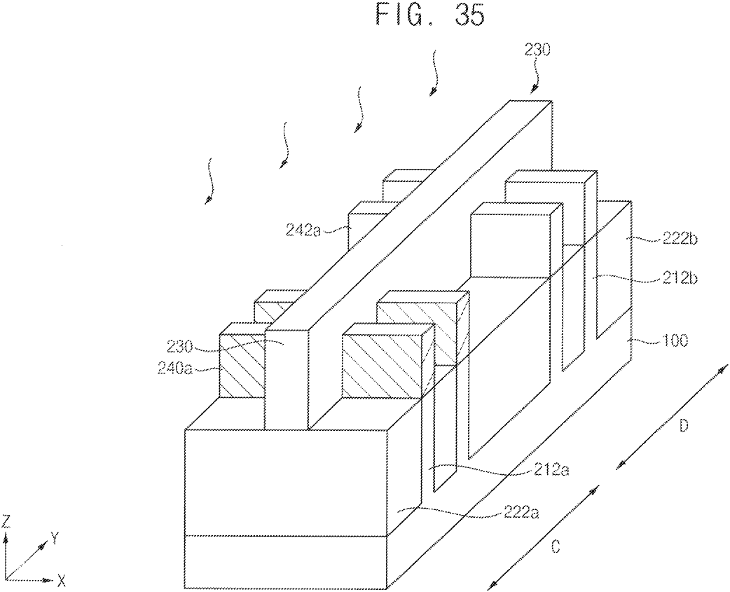

Referring to FIG. 35, an annealing process may be performed on the preliminary first source/drain layer 240 and the preliminary second source/drain layer 242, which are exposed in the first region and the second region of the substrate 100, respectively. Therefore, the first source/drain layer 240a including single crystal silicon germanium may be formed on the both sides of the dummy gate structure 230 on the first region of the substrate 100, and the second source/drain layer 242a including silicon including germanium may be formed on the both sides of the dummy gate structure 230 on the second region of the substrate 100.

The concentration of germanium included in the second source/drain layer 242a may be less than the concentration of germanium included in the first source/drain layer 240a.

When the annealing process is performed, the P-type impurities in the preliminary first source/drain layer 240 and the N-type impurities in the preliminary second source/drain layer 242 may be activated.

According to the exemplary embodiment, the annealing process may include a nanosecond laser annealing process.

A region of the first fin structure 220a covered by the dummy gate structure 230 may be provided as a preliminary first channel structure, and a region of the second fin structure 220b covered by the dummy gate structure 230 may be provided as a preliminary second channel structure. The preliminary first channel structure may have a structure in which the first silicon germanium pattern and the first silicon pattern are alternately stacked. The preliminary second channel structure may have a structure in which the second silicon germanium pattern and the second silicon pattern are alternately stacked.

The first source/drain layer 240a may have the same sidewall profile as the first fin structure 220a patterned by an anisotropic etching process. For example, the first source/drain layer 240a may have a vertical sidewall profile or a sidewall profile having an inclination that allows a width to be gradually increased downward (e.g., along the third (Z) direction) when viewed in a sectional view in the second direction. In other words, the sidewall of the first source/drain layer 240a in the second direction may not have a profile in which a portion protrudes.

In addition, the second source/drain layer 242a may have the same sidewall profile as the second fin structure 220b patterned by an anisotropic etching process. For example, the second source/drain layer 242a may have a vertical sidewall profile or a sidewall profile having an inclination that allows a width to be gradually increased downward (e.g., along the third (Z) direction) when viewed in a sectional view in the second direction. In other words, the sidewall of the second source/drain layer 242a in the second direction may not have a profile in which a portion protrudes.

As described above, the first source/drain layer 240a and the second source/drain layer 242a may be formed through a simple process.

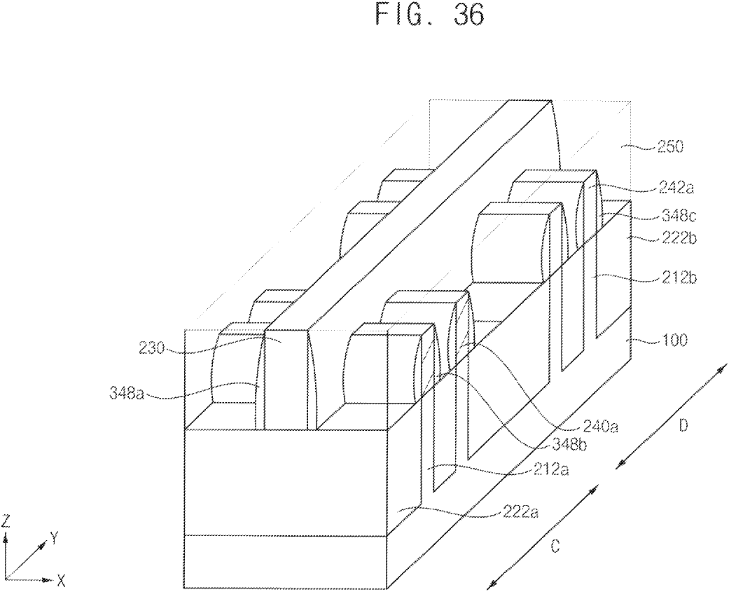

Referring to FIG. 36, first to third spacers 348a, 348b, and 348c may be formed on sidewalls of the dummy gate structure 230, the first source/drain layer 240a, and the second source/drain layer 242a, respectively.

Thereafter, an interlayer insulating layer 250 covering the first and second isolation patterns 222a and 222b, the first source/drain layer 240a, the second source/drain layer 242a, and the dummy gate structure 230 may be formed. The interlayer insulating layer 250 may be planarized until a top surface of the dummy gate structure 230 is exposed. The planarization process may be performed by a chemical mechanical polishing (CMP) process and/or an etch-back process.

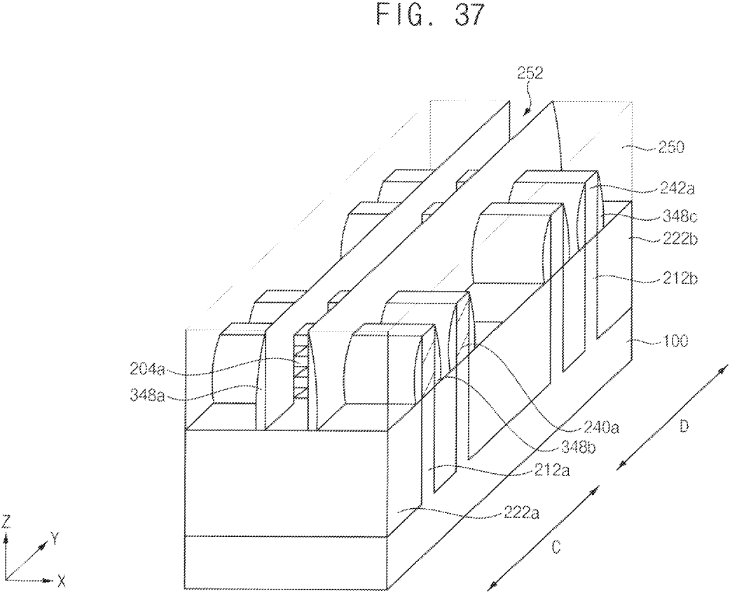

Referring to FIG. 37, the dummy gate structure 230 may be removed to form a gate trench 252. The first silicon germanium pattern 202a and the first silicon pattern 204a of the preliminary first channel structure and the second silicon germanium pattern 202b and the second silicon pattern 204b of the preliminary second channel structure may be exposed within the gate trench 252.

The first and second silicon germanium patterns 202a and 202b exposed by the gate trench 252 may be removed to form first gaps between the first silicon patterns 204a and form second gaps between the second silicon patterns 204b.

Referring to FIG. 29, a gate structure may be formed to fill the gate trench and the gaps again. Therefore, the P-type MBC FET may be formed on the first region, and the N-type MBC FET may be formed on the second region.

Although exemplary embodiments of the present disclosure have been described above, it will be understood by those of ordinary skill in the art that various changes and modifications can be made to the present disclosure without departing from the idea and scope of the present disclosure as set forth in the appended claims.

What is claimed is:

1. A semiconductor device comprising:
a substrate extending in a first direction and a second direction perpendicular to the first direction;
a first active pattern protruding from a top surface of the substrate and extending in the first direction;
an isolation pattern covering a sidewall of the first active pattern on the substrate;
first silicon patterns spaced apart from each other in a third direction on the first active pattern, the third direction perpendicular to the first direction and the second direction;
a first source/drain layer extending in the third direction from a top surface of the first active pattern on the first active pattern, and in contact with sidewalls of the first silicon patterns, wherein a sidewall of the first source/drain layer in the second direction has a constant inclination with respect to the top surface of the substrate; and
a gate structure extending in the second direction while filling a gap between the first silicon patterns on the substrate.

2. The semiconductor device of claim 1, wherein the sidewall of the first source/drain layer in the second direction has a vertical profile or has an inclination such that a width of the first source/drain layer in the second direction increases along the third direction.

3. The semiconductor device of claim 1, wherein the first source/drain layer includes single crystal silicon germanium doped with P-type impurities.

4. The semiconductor device of claim 3, wherein the P-type impurities have a concentration of 1E19 /cm³ to 1E22 /cm³.

5. The semiconductor device of claim 1, wherein a top surface of the first source/drain layer and a top surface of the first silicon pattern located at an uppermost portion are located on a same plane.

6. The semiconductor device of claim 1, wherein a first spacer is provided on a sidewall of the gate structure, and
a second spacer completely covering the sidewall of the first source/drain layer is provided.

7. The semiconductor device of claim 6, wherein a bottom surface of the first spacer formed on the sidewall of the gate structure located on the first silicon pattern located at an uppermost portion contacts a top surface of the first source/drain layer.

8. The semiconductor device of claim 1, wherein a sidewall of the gate structure contacts the first source/drain layer.

9. A semiconductor device comprising:
a substrate extending in a first direction and a second direction perpendicular to the first direction;
a first active pattern protruding from a top surface of the substrate in a first region and extending in the first direction;
first silicon patterns spaced apart from each other in a third direction on the first active pattern, the third direction perpendicular to the first direction and the second direction;
a first source/drain layer extending in the third direction from a top surface of the first active pattern on the first active pattern, and in contact with sidewalls of the first silicon patterns, wherein a sidewall of the first source/drain layer in the second has a constant inclination with respect to the top surface of the substrate;
a second active pattern protruding from the top surface of the substrate in a second region and extending in the first direction;
second silicon patterns spaced apart from each other in the third direction on the second active pattern;
a second source/drain layer extending in the third direction from a top surface of the second active pattern on the second active pattern, and in contact with sidewalls of the second silicon patterns, wherein a sidewall of the second source/drain layer in the second direction has a profile in which a portion protrudes;
a first gate structure extending in the second direction while filling a gap between the first silicon patterns on the substrate; and
a second gate structure extending in the second direction while filling a gap between the second silicon patterns on the substrate.

10. The semiconductor device of claim 9, wherein the sidewall of the first source/drain layer in the second direction has a vertical profile or has an inclination such that a width of the first source/drain layer in the second direction increases along the third direction.

11. The semiconductor device of claim 9, wherein the first source/drain layer includes single crystal silicon germanium doped with P-type impurities.

12. The semiconductor device of claim 11, wherein the P-type impurities have a concentration of 1E19 /cm³ to 1E22 /cm³.

13. The semiconductor device of claim 9, wherein a top surface of the first source/drain layer and a top surface of the first silicon pattern located at an uppermost portion are located on a same plane.

14. The semiconductor device of claim 9, wherein a sidewall of the first gate structure contacts the first source/drain layer.

15. The semiconductor device of claim 9, wherein the second source/drain layer includes single crystal silicon doped with N-type impurities.

16. The semiconductor device of claim 9, wherein the second source/drain layer has a polygonal shape in which a center portion protrudes when viewed in a sectional view in the second direction.

17. The semiconductor device of claim 9, wherein ends of the first gate structure and the second gate structure are connected to each other so that the first gate structure and the second gate structure are provided as one common gate structure.

18. The semiconductor device of claim 9, wherein an inner spacer is further formed between a sidewall of the second gate structure and the second source/drain layer.

19. A semiconductor device comprising:
a substrate extending in a first direction and a second direction perpendicular to the first direction;
a first active pattern protruding from a top surface of the substrate in a first region and extending in the first direction;
first silicon patterns spaced apart from each other in a third direction on the first active pattern, the third direction perpendicular to the first direction and the second direction;
a first source/drain layer extending in the third direction from a top surface of the first active pattern on the first active pattern, in contact with sidewalls of the first silicon patterns, and including single crystal silicon germanium doped with P-type impurities;
a second active pattern protruding from the top surface of the substrate in a second region and extending in the first direction;
second silicon patterns spaced apart from each other in the third direction on the second active pattern;
a second source/drain layer extending in the third direction from a top surface of the second active pattern on the second active pattern, in contact with sidewalls of the second silicon patterns, and including silicon including germanium doped with N-type impurities;
a first gate structure extending in the second direction while filling a gap between the first silicon patterns on the substrate; and
a second gate structure extending in the second direction while filling a gap between the second silicon patterns on the substrate,
wherein each of sidewalls of the first and second source/drain layers in the second direction has a vertical profile or has an inclination such that a width of each of the first source/drain layer and the second source/drain layer in the second direction increases along the third direction.

20. The semiconductor device of claim 19, wherein a sidewall of the first gate structure contacts the first source/drain layer, and
a sidewall of the second gate structure contacts the second source/drain layer.
